(19) United States
(12) Patent Application Publication
(10) Pub. No.: US 2008/0054429 A1
(43) Pub. Date: Mar. 6, 2008

(54) Spacers for separating components of semiconductor device assemblies, semiconductor device assemblies and systems including spacers and methods of making spacers

(76) Inventors: Todd O. Bolken, Star, ID (US); John M. Davisson, Meridian, ID (US)

Correspondence Address: TRASK BRITT, P.C./ MICRON TECHNOLOGY, P.O. BOX 2550, SALT LAKE CITY, UT, 84110, US

(21) Appl. No.: 11/509,119

(22) Filed: Aug. 25, 2006

(51) Int. Cl. H01L 23/02

(52) U.S. Cl. 257/686

(57) ABSTRACT

Preformed dielectric spacers for separating integrated circuit components and methods of forming are disclosed. A spacer wafer may be molded from a dielectric material and subsequently singulated to form a plurality of individual spacers. The molded spacer wafer may be affixed to a die attach film and film frame, and the wafer may be sawed or scored to singulate the spacers. In other embodiments, a plurality of spacers may be stamped or otherwise cut from a preformed sheet, or the spacers may be individually molded.

### BACKGROUND OF THE INVENTION

1. Field of the Invention

Embodiments of the invention relate generally to packaging of integrated circuits in the form of semiconductor devices. More particularly, various embodiments pertain to spacers for separating components of semiconductor device assemblies, semiconductor device assemblies and systems including such and methods of making such spacers.

2. State of the Art

Semiconductor technology plays a dominant role in the production of modern electronic devices. Integrated circuit components in the form of semiconductor chips, or dice, are commonly packaged together and in combination with other components to form circuits incorporating numerous electronic elements. Integrated circuit components and assemblies thereof are conventionally mounted on external circuit elements, such as printed circuit boards, which physically support the components and electrically interconnect each component with other elements of a circuit and provide external electrical connections for the circuit.

As integrated circuits become increasingly complex, integrated circuit components are often placed at greater distances, leading to longer electrical paths between them. To counteract this issue, there has been a continuous effort in the industry to create smaller and more compact integrated circuits, which enable an increase in the speed by which the integrated circuits are able to receive, process, and transmit electronic signals. This increase in speed is due in part to the decrease in resistance gained by employing shorter electrical connections within the circuit. The push for smaller and more compact integrated circuits has led to integrated circuit designs involving stacking components on top of other components, the stack being disposed on a common carrier substrate to form an assembly. Conventional assemblies of stacked integrated circuit components include multichip modules, package-on-package assemblies, and other structures. Stacking integrated circuit components may allow bond pad locations on those components to be closer in space to the bond pad locations on adjacent components, a carrier substrate, or both, for electrical coupling. Such shorter contact-to-contact distances decreases RLC-induced signal problems and increases the speed and signal quality of the integrated circuit assembly.

A multichip module (MCM) is an integrated circuit assembly which includes more than one chip. MCMs are often formed as stacked assemblies. An example of such a stacked MCM is a carrier substrate with a semiconductor die affixed to one surface thereof. A spacer is placed or formed on top of the first semiconductor die and a second semiconductor die is placed on top of the spacer. The spacer enables clearance for wire bond loops extended between terminal pads on the carrier substrate and bond pads located on the first semiconductor die when the second semiconductor die is placed thereover. Additional semiconductor dice may be added to the MCM stack, each added die being separated from the next lower die by a spacer.

Spacers may help to adhesively hold the components together prior to encapsulation (if performed), as well as providing the aforementioned clearance or standoff for loops of wire bonds used to establish electrical connections between the components and to a carrier substrate or other higher-level packaging. Spacers of this type are conventionally formed from either a layer of epoxy or other adhesive, or a die cut from a silicon wafer. U.S. Pat. No. 6,777,797 to Egawa discloses an example of an adhesive spacer. Egawa discloses using a liquid-form thermosetting or sheet-form thermoplastic adhesive to separate and mutually adhere integrated circuit components. U.S. Pat. App. Pub. No. 2006/0113643 to Loo et al. discloses a semiconductor substrate as a spacer to separate integrated circuit components.

Conventionally, silicon is formed into single-crystal ingots which may be subsequently cut with a diamond saw into round discs known as wafers. Etching and polishing processes are then required to remove sawing damage. The wafers may be processed to form the integrated circuit structures of each semiconductor die location on the wafer, and the wafer may be separated or “singulated” into the individual semiconductor dice after die fabrication is completed. Silicon wafers are sliced into the individual dice, by sawing the wafer along “streets” between the die locations, or by fracturing the wafer after scribing the surface along the streets with a diamond-tipped instrument. Some wafers may be separated into individual silicon dice before the formation of components thereon. These blank dice are conventionally used as spacers to separate other integrated circuit components. More typically, however, silicon spacers are formed from semiconductor dice which fail probe testing at the wafer level or exhibit other quality issues rendering them unsuitable for use.

The use of either an adhesive, or blank or scrapped semiconductor dice, as spacers is expensive. Additionally, conventional methods of forming spacers of epoxy, a common adhesive, are difficult to control in a production environment because of the physical property changes that occur during processing and curing of the epoxy.

One advantage of using a die cut from a semiconductor wafer as a spacer is that the same machinery used for processing, separating, and positioning dice to be formed into integrated circuit components may be used for the blank or inoperative dice to be used as spacers. In addition, the same machinery used to hold, transport and singulate dice from wafers may be used to hold, transport and singulate inoperative or unprocessed dice from wafers. After a single-crystal silicon ingot is sliced into individual wafers and those wafers are polished and smoothed, a die attach film is placed against one side of the silicon wafer. The die attach film covers one side of the wafer and extends partially beyond the perimeter of the wafer. A portion of the die attach film protruding from the perimeter of the wafer is coupled to a film frame which is used to hold and transport the wafer during subsequent processing. The die attach film and film frame act to hold the wafer in place while it is being sliced into individual dice. Once separated, the individual dice are still held in place by the film frame. Individual blank or inoperative dice are then picked from the film frame and placed as spacers in an integrated circuit component stack using the same type of die attach film, film frame, and processing equipment used for the slicing and placement of functioning semiconductor dice.

It would be desirable to provide spacers for separating integrated circuit components in the form of semiconductor chips, or dice, that are less expensive than conventional silicon spacers and more precisely dimensioned than is possible with epoxy pillows. It would also be desirable to provide a method of producing and positioning spacers using, at least in part, conventional semiconductor wafer processing equipment.

### BRIEF DESCRIPTION OF THE SEVERAL VIEWS OF THE DRAWINGS

FIG. 1A is a top view of an embodiment of a spacer of the invention;

FIG. 1B is a side view of the embodiment of the spacer as shown in FIG. 1A;

FIG. 1C is a perspective view of the embodiment of the spacer as shown in FIGS. 1A and 1B;

FIG. 2A is a top view of another embodiment of a spacer of the invention including a conductive via;

FIG. 2B is a cross-sectional side view of the embodiment of the spacer as shown in FIG. 2A;

FIG. 2C is a perspective view of the embodiment of the spacer as shown in FIGS. 2A and 2B;

FIG. 3 is a cross-sectional side view of a mold containing an embodiment of a molded spacer wafer of the invention;

FIG. 4A is a top view of an embodiment of a spacer wafer of the invention;

FIG. 4B is a side view of the spacer wafer as shown in FIG. 4A;

FIG. 4C is a perspective view of the spacer wafer as shown in FIGS. 4A and 4B;

FIG. 5A is a top view of an embodiment of a spacer wafer of the invention adhered to a die attach film;

FIG. 5B is a side view of the embodiment of the spacer wafer adhered to the die attach film as shown in FIG. 5A;

FIG. 6A is a top view of a diced and unsingulated spacer wafer of the invention adhered to a die attach film and support on a film frame;

FIG. 6B is a cross-sectional side view of the film frame, die attach film, and diced and unsingulated spacer wafer as shown in FIG. 6A with a pick and place tool thereover;

FIG. 7 is a cross-sectional side view of a mold configured to form and containing an embodiment of an individual spacer of the invention;

FIG. 8 is a cross-sectional side view of a mold configured to form and containing a plurality of spacers of the invention;

FIG. 9 is a partial side view of an embodiment of an integrated circuit assembly of the invention including multiple stacked integrated circuit components in the form of semiconductor dice electrically coupled to a lead frame and separated by spacers;

FIG. 10 is a side view of an embodiment of a package-on-package integrated circuit configuration of the invention;

FIG. 11 is a side view of an embodiment of an integrated circuit assembly of the invention including an integrated circuit component separated from a carrier substrate by a spacer;

FIG. 12A is a cross-sectional, schematic side view of a transfer mold with flowable material within a reservoir in accordance with an embodiment of the invention;

FIG. 12B is a cross-sectional, schematic side view of the transfer mold of FIG. 12A with flowable material forced by a ram from the reservoir through a runner and into a mold cavity configured for formation of a spacer, in accordance with an embodiment of the invention;

FIG. 12C is a cross-sectional, schematic side view of the transfer mold of FIG. 12A with cured material forming a cull and sprue and with a molded part in the form of a molded spacer ejected by an ejector pin in accordance with an embodiment of the invention;

FIG. 13 is a partially cut-away, schematic side view of an embodiment of an injection mold system suitable for forming spacers of the invention;

FIG. 14A is a cross-sectional, schematic side view of an embodiment of a punch press prior to cutting a spacer of the invention therefrom;

FIG. 14B is a cross-sectional, schematic side view of the embodiment of the punch press of FIG. 14A subsequent to cutting a spacer of the invention therefrom;

FIG. 15 is a schematic side view of an embodiment of a system configured to form spacers from a sheet of suitable material; and

FIG. 16 is a schematic depiction of an embodiment of an electronic system including at least one spacer according to an embodiment of the present invention.

### DETAILED DESCRIPTION OF THE ILLUSTRATED EMBODIMENTS

In the description which follows, like features and elements have been identified by the same or similar reference numerals for ease of identification and enhanced understanding of the disclosure hereof. Such identification is by way of convenience for the reader only, however, and is not limiting of the present invention or an implication that features and elements of various components and embodiments identified by like reference numerals are identical or constrained to identical functions.

While the making and using of various embodiments of the present invention are discussed in detail below, it should be appreciated that the present invention provides many applicable inventive concepts which may be embodied in a wide variety of specific contexts. The specific embodiments discussed herein are merely illustrative of specific ways to make and use the invention and do not delimit the scope of the invention.

Embodiments of the invention include methods for forming a spacer sized and shaped for separating integrated circuit components, preformed spacers for separating integrated circuit components, and methods for fabricating integrated circuit devices including spacers.

In one embodiment, a spacer sized and shaped for separating components of a semiconductor device assembly comprises a polymer matrix material, for example a thermoplastic, a thermosetting plastic, or any other material exhibiting desired mechanical and electrical (dielectric) characteristics and suitable for use with embodiments of methods of fabrication of the invention. The spacer may be about 20 μm to about 150 μm thick and, for many applications, about 40 μm to about 80 μm thick. The spacer may, optionally, include at least one conductive via therethrough, enabling an electrical connection to be made through the spacer.

Another embodiment comprises a method of forming a spacer sized and shaped for separating stacked components of a semiconductor device assembly. The method comprises placing a flowable material into a mold cavity configured to form a spacer wafer, solidifying the flowable material within the mold cavity, and removing the solidified material in the form of the spacer wafer from the mold cavity, the spacer wafer exhibiting a substantially planar and generally round disc shape with two opposing, major planar surfaces and a peripheral surface therebetween. The spacer wafer may be sized and shaped to be held and processed with conventional equipment used for processing conventional silicon wafers. The processing may include applying a die attach film to a first surface of the spacer wafer, a portion of the die attach film extending at least partially beyond the perimeter of the spacer wafer, attaching a film frame to at least a portion of the die attach film extending beyond the perimeter of the spacer wafer and dicing the spacer wafer to form individual spacers sized and shaped to separate components of a semiconductor device assembly. Singulated spacers may then be removed from the diced spacer wafer using a conventional pick-and-place apparatus. Optionally, the thickness of the wafer may be reduced prior to dicing by abrasive planarization (including without limitation chemical-mechanical planarization), polishing, grinding or any other suitable technique known in the art.

In another embodiment, a mold cavity may be sized to form an individual spacer, sized and shaped to separate components of a semiconductor device assembly without requiring significant subsequent processing.

In yet another embodiment, a plurality of individual spacers, sized and shaped to separate components of a semiconductor device assembly, is formed together in a common mold with spacer locations separated by partitions in the form of runners. The use of partitions enables a plurality of spacers to be formed in a common mold without requiring significant subsequent processing, such as singulation.

In yet another embodiment, a substantially planar sheet of suitable material may be used to form individual spacers, or spacer wafers, by stamping or punching. If stamped wafers are formed, they may be subsequently singulated to form individual spacers. The sheet of material may, itself, be formed by any molding method disclosed herein or otherwise comprising the state of the art.

In a further embodiment, a substantially planar sheet of suitable material may be cut into strips, and the strips segmented to produce individual spacers.

In other embodiments, preformed, molded spacers may be formed by compression molding, injection molding, transfer molding, or any other suitable molding method.

Compression molding may comprise introducing flowable dielectric material, which may be preheated, into a heated mold cavity. Pressure is then applied to force the flowable dielectric material into contact with the entire mold cavity, and heat and pressure are maintained as required until the material has solidified.

Injection molding may comprise injecting flowable dielectric material into a mold cavity, and then solidifying the flowable dielectric material.

Transfer molding may comprise loading dielectric material into a chamber known as a pot, and preheating the material to a flowable state. The heated, flowable dielectric material is then forced by a plunger from the pot through channels known as a sprue and runner system into the mold cavities.

Another embodiment of the present invention comprises an integrated circuit device assembly, including at least two components separated by a spacer in the form of a preformed polymer matrix material. The at least two components may each individually comprise a semiconductor die, an interposer substrate, a printed circuit board or other carrier substrate, or any other electronic component known in the art.

Yet another embodiment of the present invention comprises a method of forming a semiconductor device assembly, comprising locating a first component, placing a preformed spacer against the first component, and positioning a second component against the preformed spacer on a side opposite the component. The components may each individually comprise a semiconductor die, an interposer substrate, a printed circuit board or other carrier substrate, or any other integrated circuit component known in the art. A single tool or machine may be employed to position and place both the components, such as semiconductor dice, and the preformed spacer.

Other features and advantages of the present invention will become apparent to those of skill in the art through consideration of the ensuing description, the accompanying drawings, and the appended claims.

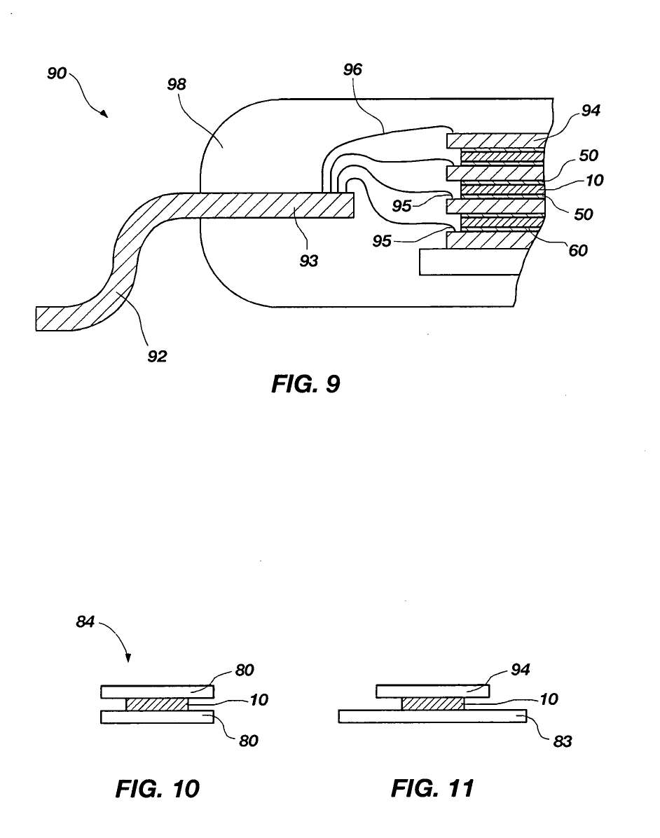

The present invention relates to semiconductor device assemblies, particularly semiconductor device assemblies comprising stacked components. A spacer of the present invention may separate the stacked components. FIG. 9 depicts a multi-chip module (MCM) 90 including stacked components in the form of semiconductor dice 94. The semiconductor dice 94 of the MCM 90 are electrically coupled to a lead frame 92 through bond wires 96. The bond wires 96 extend in loops from contact locations, for example bond pads 95, on the semiconductor dice 94 to inner ends of lead fingers 93. Therefore, adequate clearance is required above the bond pads 95 on each semiconductor die 94 below the uppermost semiconductor die 94 to prevent the bond wire loops from contacting and shorting against a higher semiconductor die 94 in the stack. Thus, the semiconductor dice 94 must be spaced a given distance from one another. Preformed spacers 10 of the present invention may be used to vertically separate the semiconductor dice 94, providing the desired clearance above the bond pads 95 for the bond wires 96. The bond pads 95 may be disposed, for example, along one or more peripheral edges of the active surfaces of the semiconductor dice 94, and the spacers 10 may be disposed centrally on the semiconductor dice 94, or at least inboard of the bond pads 95.

Embodiments of spacers 10 of the present invention may be formed of a material suitable to minimize stress caused by differences in coefficient of thermal expansion (CTE) between semiconductor dice 94 and an encapsulant material 98 that surrounds and protects the semiconductor dice 94. In one embodiment, the CTE of the material of the spacer 10 may be selected to be substantially similar to the CTE of the encapsulant material 98 enabling even Z-axis (vertical) expansion of the MCM 90. For example, the spacer 10 may comprise a thermoset material such as a thermosetting plastic, for example, a thermoset epoxy, or may comprise a thermoplastic material. In another embodiment, the CTE of the material of the spacer 10 may be selected to match the CTE of the semiconductor dice 94. For example, the spacer 10 may comprise a silicon-filled epoxy. In still another embodiment, the CTE of the material of the spacer 10 may be tailored to be intermediate the CTE of the semiconductor dice 94 and the encapsulant material 98.

Spacers 10 may include an adhesive 50 disposed on a top and a bottom surface thereof. The adhesive 50 on one surface of the spacer 10 may be used to attach the spacer 10 with a first semiconductor die 94, and the adhesive 50 on an opposing surface of the spacer 10 may attach the spacer 10 with a second semiconductor component 94 disposed thereon, to form a die stack. Of course, more than two semiconductor dice 94 may be placed in a stack with spacers 10 disposed therebetween.

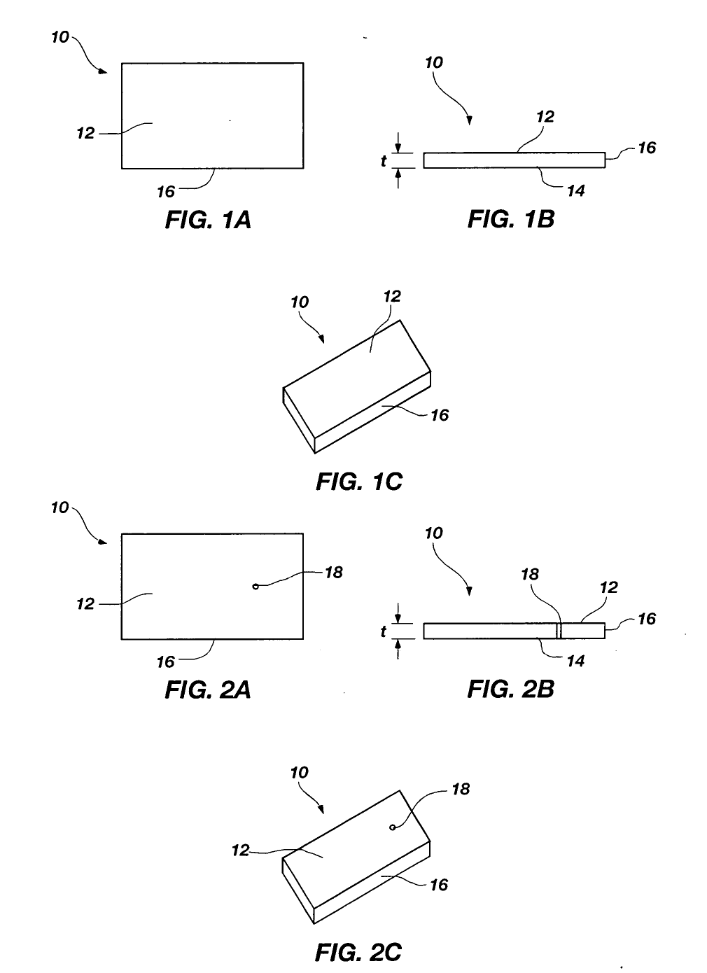

FIGS. 1A-1C illustrate a spacer 10 in accordance with the present invention. The spacer 10 has a first surface 12 and an opposing, parallel second surface 14 which are separated by side surfaces 16. The spacer 10 may be sized and shaped for separating integrated circuit components, and may comprise a polymer matrix material. The polymer matrix material may be a thermoplastic, a thermosetting plastic, or any other material known in the art that may be molded to a desired size and shape. Subsequent to molding, the polymer matrix material may cure to a rigid material. The spacer 10 may have, for example, a thickness t between about 20 μm and about 150 μm and, for many applications, between about 40 μm and about 80μm.

FIGS. 2A-2C depict a spacer 10 with a conductive via 18 placed through the center of the spacer 10, electrically connecting first surface 12 and second surface 14. The electrically conductive via 18 enables an electrical connection through the spacer 10, for example between an integrated circuit component such as a semiconductor die disposed adjacent to the first surface 12 of the spacer 10 and another integrated circuit component such as another semiconductor die, an interposer substrate or a carrier substrate, disposed adjacent to the second surface 14 of the spacer 10. Spacer 10 may include any number of conductive vias 18, configured, for example, in an array to align with a ball grid array, bond pads or terminal pads of integrated circuit components, or combinations thereof.

The conductive via 18 may be formed by any suitable method known by those of ordinary skill in the art such as etching, drilling, or laser ablation. Etching the via 18 may require the application and patterning of an etchant-resistive material such as a photoresist material on a side of the spacer 10, followed by etching with a suitable wet or dry etchant. Alternatively, via 18 may be formed during the molding process using a mold cavity or inserts placed therein, configured to form a spacer 10 having vias 18 therethrough. The internal structure of via 18 may be of round, polygonal or any other suitable cross-sectional shape. After formation, the via 18 may then be filled with a conductive material such as aluminum, nickel, gold, silver, an alloy (including solders), conductive or conductor-filled epoxy, or any other suitable conductive material known in the art. Preformed conductive structures such as wires, pillars, studs or columns may be inserted into holes previously formed in a spacer 10, or mechanically driven therethrough. If a plurality of spacers 10 with conductive vias 18 is formed as part of a spacer wafer 20 as described below, the conductive vias may desirably be formed at the wafer level using conventional equipment for forming and filling vias in semiconductor wafers.

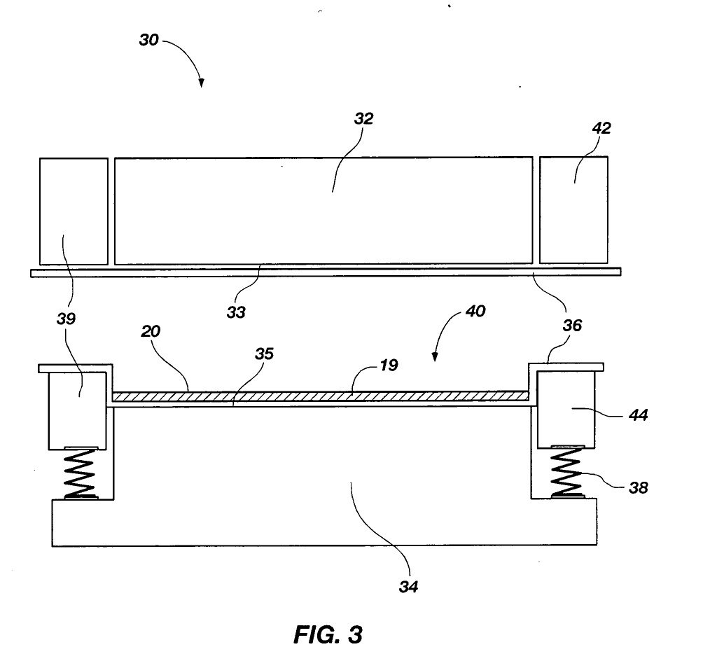

FIG. 3 shows an embodiment of a mold 30 for forming a spacer wafer 20 of the present invention. The spacer wafer 20 may be singulated to form individual spacers 10 of the present invention. The mold 30 comprises a top die set 32 and a bottom die set 34, and a mold body 39. The mold body 39 may be configured to initiate vertical movement of the top die set 32 and/or the bottom die set 34, moving the top and bottom die sets 32, 34 toward or away from one another. A lower portion 44 of the mold body 39 may be biased toward a top portion 42 of the mold body 39 by at least one biasing element 38. The bottom die set 34 may include a substantially planar bottom mold surface 35 facing the top die set 32. The lower portion 44 of the mold body 39 may be positioned about a perimeter of the bottom die set surface 35, defining a mold cavity 40. A mold release film 36 may be used to line the mold cavity 40, and may ease the extraction of a spacer wafer 20 from the mold 30, after formation thereof.

The mold cavity 40 may be sized and shaped to form a planar and generally round spacer wafer 20. During the molding process, a flowable dielectric material 19 may be deposited into the mold cavity 40. The flowable dielectric material 19 may comprise any suitable molding compound, for example powder, pellets, liquid or preform. The top die set 32 and the bottom die set 34 may be brought towards each other with the flowable dielectric material 19 disposed therebetween. As the top portion 42 of the mold body forces against the lower portion 44 of the mold body 39 the biasing element 38 may deform to enable the flowable dielectric material 19 to be compressed to the desired thickness of the spacer wafer 20. The flowable dielectric material may solidify, for example, by curing, into a spacer wafer 20 of (for example) a polymer matrix material within the mold cavity 40. The spacer wafer 20 may be removed from the mold cavity 40. The mold release film 36 may line both mold cavity 40 and a surface 33 of the top die set 32 facing the mold cavity 40, and may ease the extraction of the spacer wafer 20 from the mold 30. The spacer wafer 20 is thus molded between the substantially planar surface 35 of the bottom die set 34 and the substantially planar surface 33 of the top die set 32, and bounded by the lower portion 44 of the mold body 39.

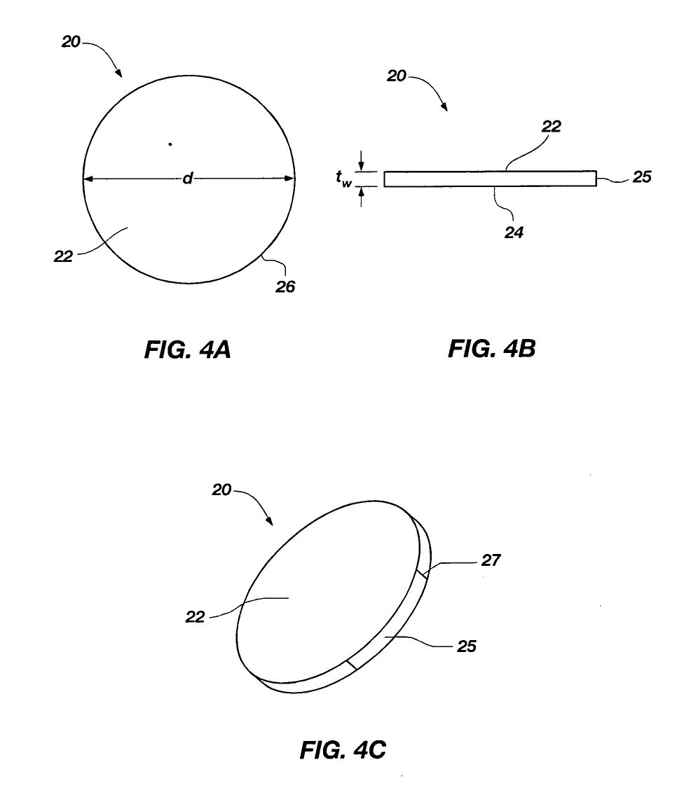

FIGS. 4A-4C depict the spacer wafer 20 once it has been extracted from the mold 30. The spacer wafer 20 has a first surface 22 and an opposing second surface 24, separated by a side surface 25 extending around a perimeter of the first surface 22 and a perimeter of the opposing second surface 24. The spacer wafer 20 as shown is substantially planar and generally round, and may optionally include a side flat thereon similar to that of semiconductor wafers, although it may comprise another shape. For example, the spacer wafer 20 may be substantially planar and rectangular or square. The side surface 25 of the spacer wafer 20 may optionally include notches or other markings 27 that may be useful to provide information about the wafer or guidance during orientation.

The molded spacer wafer 20 may have, for example, a diameter d of about 200 mm or about 300 mm, to facilitate use of conventional wafer handling equipment, although larger and smaller spacer wafers are within the scope of the present invention. Optionally, the thickness of the molded spacer wafer 20 may also be reduced by abrasive planarization (including chemical-mechanical planarization), polishing, grinding or any other technique known in the art. As previously noted, the spacer wafer 20 may be sized and shaped to be held and processed by conventional equipment used for processing conventional silicon and other semiconductor wafers. Thus, processing of a spacer wafer 20 may include applying a die attach film to a first surface of the spacer wafer, a portion of the die attach film extending at least partially beyond the perimeter of the spacer wafer; attaching a film frame to at least a portion of the die attach film extending beyond the perimeter of the spacer wafer; and slicing the spacer wafer to form spacers suitably sized and shaped to separate components of a semiconductor device asembly.

The molded spacer wafer 20 may be sliced, or cut, with a dicing saw, a water or slurry jet, a hot wire, or other techniques known to those of ordinary skill in the art. The molded spacer wafer 20 may be completely sawn through for dicing into individual spacers 10, or the molded spacer wafer 20 may be scribed or sawn to a partial depth. The scribed or partially sawn wafer 20 may be fractured along the partially scribed or sawn boundaries between locations of individual spacers 10 to form the individual spacers 10, provided the material of spacer wafer 20 is selected to be suitably frangible.

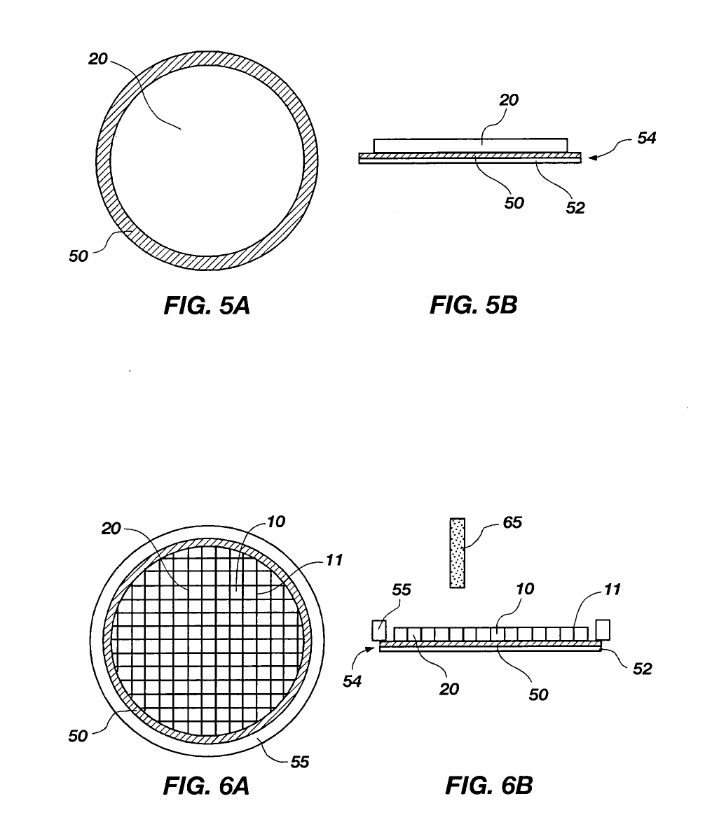

Optionally, the spacer wafer 20 may be attached to a die attach film 54 prior to dicing, as illustrated in FIGS. 5A-5B. The molded spacer wafer 20 is generally centered on the die attach film 54 with at least a portion of the die attach film 54 extending beyond the perimeter 26 of the spacer wafer 20. A film frame 55 is attached to the die attach film 54 beyond a perimeter 26 of the spacer wafer 20 as shown in FIGS. 6A-6B.

The spacer wafer 20 attached to the die attach film 54 and secured by the film frame 55 may be singulated into individual spacers 10 using conventional methods used to singulate silicon wafers to form individual dice or spacers. The spacer wafer 20 may be separated along straight lines 11 (which would correspond to streets between semiconductor dice on a conventional silicon wafer) to form spacers 10 having square or rectangular cross-sections. Once the spacers 10 are separated, they may be picked from the film frame 55 and placed on a component such as a semiconductor die 94 (FIG. 9) using a placing tool 65. Another component such as a second semiconductor die 94 may be placed upon the spacer 10 to form a stack, (FIG. 9).

The die attach film 54 may comprise a support layer 52 and an adhesive layer 50. The support layer 52 may retain the spacers 10 in position during singulation of the spacer wafer 20. The adhesive layer 50 may be severed with the spacers 10, and may be useful to adhere a spacer 10 to a component such as a semiconductor die 94 within a stack of such components. A UV treatment may be used to decouple the adhesive layer 50 from the support layer 52.

Optionally, a die attach film 54 may be disposed on both the first surface 12 and the opposing second surface 14 of the spacer wafer 20. The adhesive layer 50 of each die attach film 54 may be severed with spacers 10, decoupled from the support layer 52, and subsequently be used to adhere a spacer 10 at the first surface 12 to a component and at the second surface 14 to another component. Alternatively, an adhesive may be placed on a component such as a semiconductor die 94 prior to the placement of the spacer 10. The preplaced adhesive may be used to secure the spacer 10 to the semiconductor die 94.

Thus, the spacer wafer 20 may be molded, and may be formed less expensively than a conventional silicon wafer. Conventional wafer processing equipment may be used to singulate the molded spacer wafer 20 into individual spacers 10, and to pick and place the spacers 10 onto a stack. Other methods and apparatus for singulating the molded spacer wafer 20 and placing the individual spacers 10 are also within the scope of the present invention, the present invention not being limited to the use of conventional wafer processing equipment.

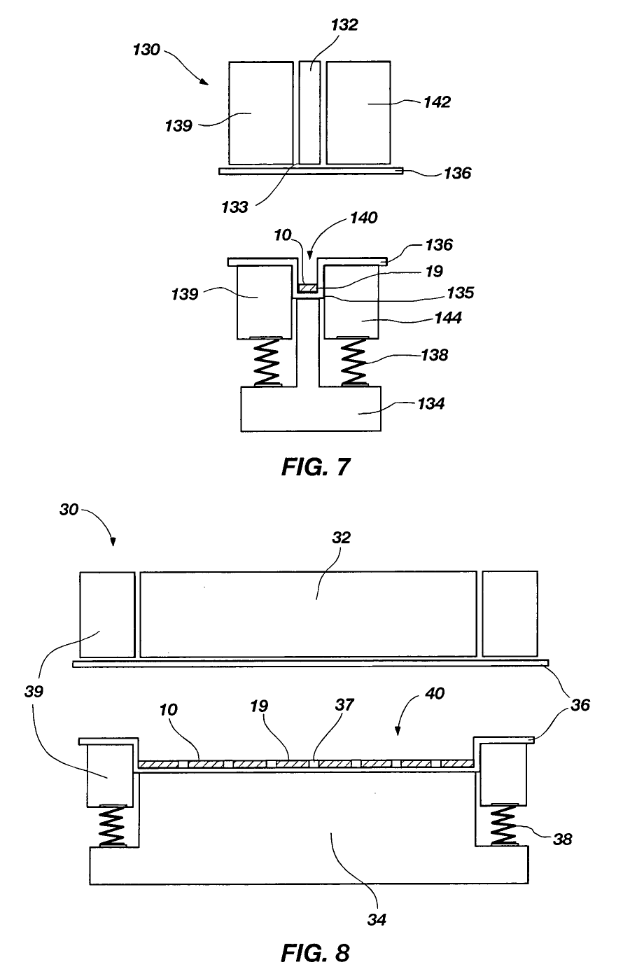

Another embodiment of a method for forming a molded spacer 10 comprises molding each individual spacer 10 into the desired size and shape. In other words, the spacer 10 may be directly molded to a desired size, shape, dimensions and tolerances, rather than molding a spacer wafer 20, and singulating the spacer wafer 20 to form spacers 10. FIG. 7 depicts a mold 130 configured to form a single spacer 10. The mold 130 may include a mold cavity 140, which may be round, square, or rectangular, or any other desired shape for the spacer 10. The mold 130 may include a top die set 132 and a bottom die set 134, and a mold body 139. The mold body 139 may be configured to initiate vertical movement of the top die set 132 and/or the bottom die set 134, bringing the top and bottom die sets 132, 134 toward or away from one another. A lower portion 144 of the mold body 139 may be biased toward a top portion 142 of the mold body 139 by a biasing element 138. The bottom die set 134 may include a substantially planar bottom mold surface 135 facing the top die set 132. The lower portion 144 of the mold body 139 may be positioned about a perimeter of the bottom mold surface 135, defining a mold cavity 140. A mold release film 136 may line the mold cavity 140, and may ease the extraction of a spacer 10 from the mold 130, after formation thereof.

The mold cavity 140 may be sized and shaped to form a planar and generally square, rectangular, or round spacer 10. During the molding process, a flowable dielectric material 19 may be deposited into the mold cavity 140, and the top die set 132 and the bottom die set 134 may be brought towards each other. As the top portion 142 of the mold body 139 forces against the lower portion 144 of the mold body 139 the biasing element 138 may deform to enable the flowable dielectric material 19 to be compressed to the desired thickness of the spacer 10. The flowable dielectric material 19 may solidify, for example, by curing, into a spacer 10 of a rigid polymer matrix material within the mold cavity 140. The spacer 10 may be removed from the mold cavity 140. The mold release film 136 may line both mold cavity 140 and a surface 133 of the top die set 132 facing the mold cavity 140, and may ease the extraction of the spacer 10 from the mold 130.

Die attach film 54 may be applied to the spacer 10, and the spacer may be positioned to separate components of a semiconductor device assembly, as previously discussed. Optionally, an adhesive 60 may be used to adhere the spacer 10 to an adjacent component such as a semiconductor die 94, as shown in FIG. 9. The adhesive 60 may be applied to the spacer 10, the semiconductor die 94, or both.

FIG. 8 depicts the mold 30 including a plurality of runners 37 within the mold cavity 40. The runners 37 may be removable, and may include a first plurality of runners substantially parallel to one another, and a second plurality of substantially parallel runners, the first plurality and the second plurality being substantially orthogonal to one another. Thus, the mold cavity 40 may be divided into a plurality of substantially square or rectangular sub-cavities. A flowable dielectric material 19 may be deposited in each sub-cavity, and hardened to form a spacer 10.

Other methods of forming molded spacers 10 are also within the scope of the present invention. The molded spacer wafers 20 may be formed using compression molding as discussed previously, transfer molding, or injection molding. The molded spacer wafer 20 may be singulated to form spacers 10, as described hereinabove. Likewise, the individual spacers 10 may be molded to the desired size and shape using compression molding, transfer molding, or injection molding. A spacer wafer 20 may be stamped from a preformed sheet and then singulated into individual spacers 10 as discussed hereinabove, or a spacer 10 may be individually stamped from a preformed sheet. A spacer wafer 20 or a spacer 10 may also be thinned after fabrication, for example, by abrasive planarization, polishing, or grinding.

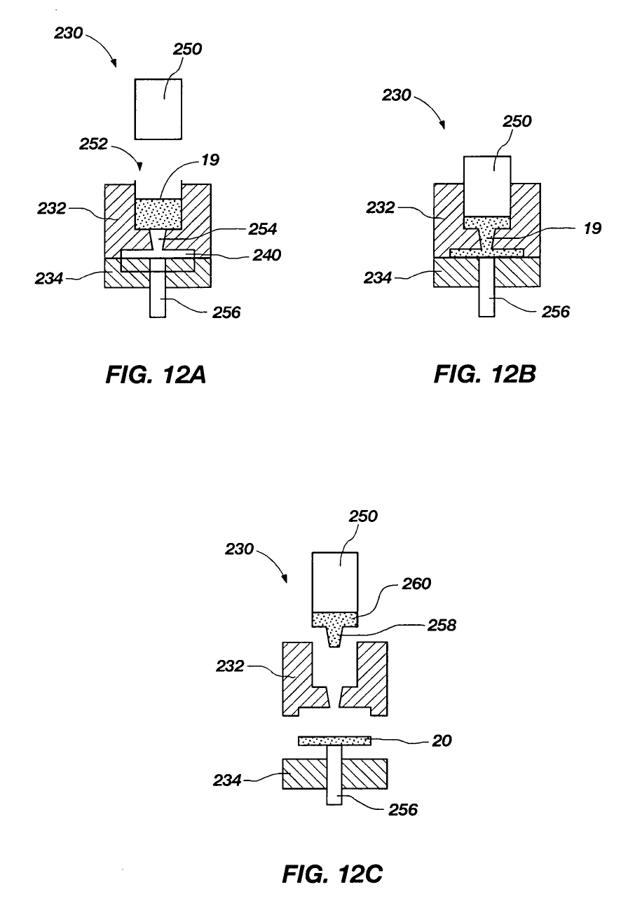

FIGS. 12A-12C schematically show a mold 230 suitable for a transfer molding process for forming a wafer 20. Spacers 10 may also be molded to the desired size and shape using a similar transfer molding process. Transfer mold 230 comprises a top die set 232 and a bottom die set 234. The top die set 232 includes a pot 252 attached to a runner 254, also known as a sprue, that feeds into a transfer mold cavity 240. The transfer mold cavity 240 is positioned between the top die set 232 and the bottom die set 234. A flowable dielectric material 19 is placed into the pot 252 where it may be heated. Pressure may then be applied to the flowable dielectric material 19 by a ram or plunger 250 as shown in FIG. 12B. This pressure forces the flowable dielectric material 19 through the runner 254 and into the transfer mold cavity 240 where it may cure, forming a spacer wafer 20 comprising a polymer matrix material. The top die set 232 and the bottom die set 234 are separated and the ram or plunger 250 is extracted as shown in FIG. 12C. A portion of the cured material remains attached to the ram or plunger 250 forming the cull 260 and the sprue 258 which are conventionally disposed of. The molded spacer wafer 20 is ejected from the transfer mold 230 by an ejector pin 256 of the bottom die set 234.

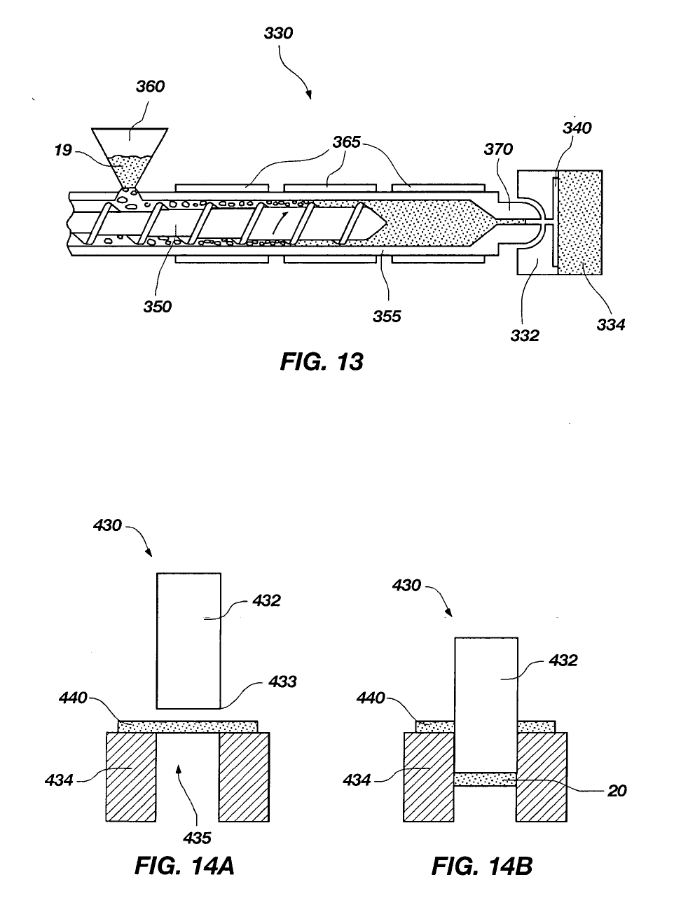

FIG. 13 shows a mold 330 suitable for an injection molding process for forming a spacer wafer 20. An injection molding process may also be useful for molding individual spacers 10 of the present invention to the desired size and shape. Injection mold 330 comprises a hopper 360, an injection barrel 355, and a nozzle 370. Flowable dielectric material 19 is placed in the hopper 360 where it is steadily fed into the injection barrel 355. A reciprocating screw 350 forces the flowable dielectric material 19 along the interior of the injection barrel 355 toward the nozzle 370. This forcing action may also be performed by a hydraulic ram or any other device known in the art. The injection barrel 355 is surrounded by heaters 365 that heat the flowable dielectric material 19 as it travels along the length of the injection barrel 355. An injection mold cavity 340 is formed between a top die set 332 and a bottom die set 334. The heated flowable dielectric material 19 is forced out of the injection barrel 355, through a nozzle 370 and into the injection mold cavity 340 where it may cure into a spacer wafer 20 of the desired size and shape. The top die set 332 and the bottom die set 334 may be separated to enable removal of the spacer wafer 20.

FIGS. 14A and 14B show a punch press 430 suitable for a cutting process for forming spacer wafer 20. Individual spacers 10 may likewise be formed by a cutting process. Punch press 430 comprises a punch 432 and a punch die 434. The punch 432 is sized and shaped to fit partially within a cavity 435 of the punch die 434. The punch 432 includes a bottom edge 433 that may be sharpened to facilitate piercing. The bottom edge 433 need not be substantially flat, but may also be angled or concave. A work piece 440 is positioned between the punch 432 and the punch die 434. The work piece 440 may be a substantially planar sheet of polymer matrix material. The punch 432 is forced against the work piece 440 and partially into the punch die cavity 435 causing the work piece 440 to shear, forming a spacer wafer 20. The work piece 440 may be repositioned and the process repeated.

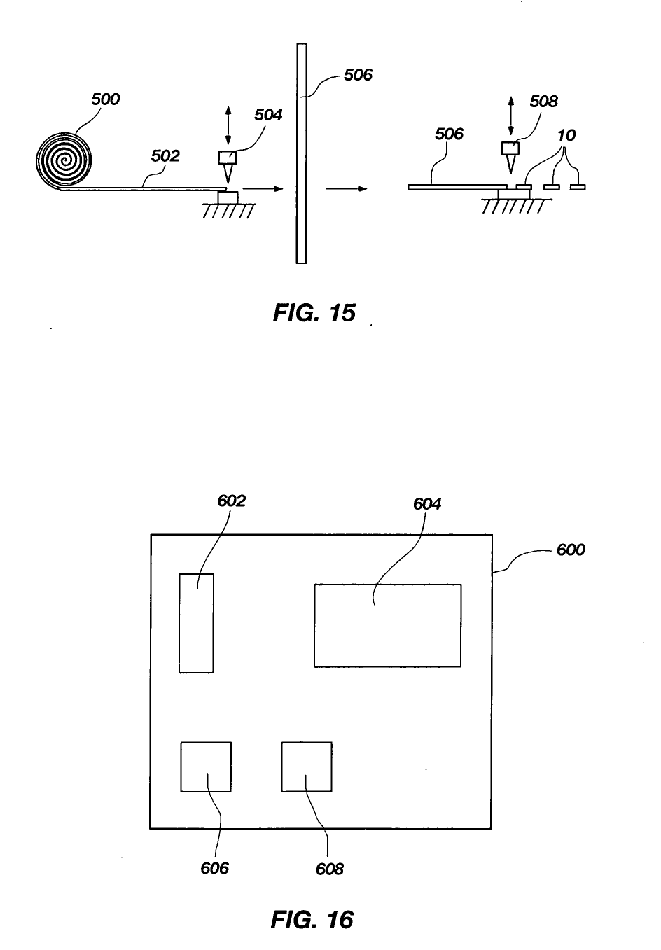

As a further approach to forming spacers 10 according to an embodiment of the present invention and with reference to FIG. 15, a preformed sheet of material 502 of appropriate thickness fed from a roll of sheet material 500 may be severed using automated cutter 504 into strips 506 of a width corresponding to one desired lateral dimension of a spacer 10 by cutting transverse to the direction of feed of the sheet from the roll, and the strips 506 fed through another automated cutter 508 to be severed into individual spacers 10 at intervals corresponding to the other desired lateral dimension of a spacer 10. Such a technique would permit easy adjustment of the length, width and thickness (by selection of a sheet material 500 of desired thickness) of the spacers 10. As known to those of ordinary skill in the art, the depicted system may be computer-controlled in terms of rate of feed of the sheet material and timing of automated cutters 504 and 508 to facilitate adjustment of lateral dimensions (width and length) of spacers 10.

FIG. 9 depicts a spacer 10 of the present invention separating components of a semiconductor device assembly in the form of semiconductor dice 94; however, if desired, the spacers of the present invention may also be useful to separate packaged integrated circuit components 80, for example in a package-on-package configuration 84 as shown in FIG. 10. The spacer 10 of the present invention may also be used to separate a single component in the form of a semiconductor die 94 from a substrate 83, for example an interposer substrate, a circuit board such as (for example) a motherboard, or other type of carrier substrate as shown in FIG. 11.

FIG. 16 of the drawings depicts, in schematic block form, an embodiment of an electronic system 600 including at least one semiconductor device assembly according to one or more embodiments of the present invention. System 600 may comprise, by way of nonlimiting example only, a personal computer, a server, a cell phone, a personal digital assistant (PDA), a camera, or any other system comprising a processor 602 and memory 604 and, optionally, an input device 606 and an output device 608. Memory 604 may comprise a semiconductor device assembly according to an embodiment of the present invention, or memory 604 may be combined with processor 602 in a semiconductor device assembly according to an embodiment of the present invention.

Although the foregoing description contains many specific details, these should not be construed as limiting the scope of the present invention, but merely as providing illustrations of some embodiments. Similarly, other embodiments of the invention may be devised which do not depart from the spirit or scope of the present invention. Moreover, features from different embodiments of the invention may be employed in combination. The scope of the invention is, therefore, indicated and limited only by the appended claims and their legal equivalents, rather than by the foregoing description. All additions, deletions, and modifications to the embodiments of the invention, as disclosed herein, which fall within the meaning and scope of the claims are embraced thereby.

What is claimed is:

1. A multi-chip module, comprising:
a substrate;
a first semiconductor device having an active surface including a plurality of bond pads thereon and an opposing back side;
a second semiconductor device, the second semiconductor device having an active surface including a plurality of bond pads thereon and an opposing back side; and
a preformed spacer comprising a polymer matrix material interposed between the first semiconductor device active surface and the second semiconductor device back side;
wherein the back side of the first semiconductor device is disposed proximate the substrate.

2. The multi-chip module of claim 1, wherein the polymer matrix material is one of a thermoplastic and a thermosetting plastic.

3. The multi-chip module of claim 1, wherein the preformed spacer has a thickness of about 20 μm to about 150 μm.

4. The multi-chip module of claim 4, wherein the preformed spacer has a thickness of about 40 μm to about 80 μm.

5. The multi-chip module of claim 1, further comprising at least one conductive via extending at least partially through a thickness of the preformed spacer.

6. The multi-chip module of claim 5, wherein the at least one conductive via extends completely through the thickness of the preformed spacer.

7. A method of using a spacer for separating components of a semiconductor device assembly, the method comprising:
placing a flowable dielectric material into a mold cavity;
molding and solidifying the flowable dielectric material within the mold cavity;
removing the solidified dielectric material from the mold cavity; and
positioning at least a portion of the solidified dielectric material configured as a spacer on a first component; and
positioning a second component on the at least a portion of the solidified dielectric material.

8. The method of claim 7, further comprising configuring the mold cavity to shape the solidified dielectric material in the form of a spacer wafer having a first substantially planar surface, a second, opposing substantially planar surface, and a side surface extending from a perimeter of the first surface to a perimeter of the second surface.

9. The method of claim 8, further comprising:
applying a die attach film to the first surface of the spacer wafer, a portion of the die attach film extending at least partially beyond the perimeter of the first surface of the spacer wafer;
attaching a film frame to at least a portion of the die attach film extending beyond the perimeter of the first surface of the spacer wafer; and
severing the wafer to form at least one spacer.

10. The method of claim 7, further comprising solidifying the flowable dielectric material configured as at least one individual spacer.

11. The method of claim 10, wherein the placing the flowable dielectric material into a mold cavity comprises placing the flowable dielectric material into a mold cavity having a first plurality of parallel runners and a second plurality of parallel runners positioned therein, the first plurality of parallel runners and the second plurality of parallel runners being orthogonal to one another and defining sub-cavities each configured to form an individual spacer.

12. The method of claim 7, further comprising stamping at least one spacer from the solidified dielectric material.

13. The method of claim 7, further comprising:
cutting at least one spacer wafer from the solidified material;
applying a die attach film to one side of the at least one spacer wafer, a portion of the die attach film extending at least partially beyond the perimeter of the at least one spacer wafer;
attaching a film frame to at least a portion of the die attach film extending beyond the perimeter of the at least one spacer wafer; and
severing the at least one spacer wafer to form at least one spacer.

14. The method of claim 7, further comprising:
reducing the thickness of the solidified dielectric material by abrasive planarization, chemical-mechanical planarization, polishing, or grinding.

15. The method of claim 7, wherein solidifying the flowable dielectric material comprises compression molding the flowable dielectric material.

16. The method of claim 7, wherein placing a flowable dielectric material into a mold cavity further comprises:
injecting a flowable dielectric material into a mold cavity.

17. The method of claim 7, wherein placing a flowable dielectric material into a mold cavity further comprises:
forcing flowable dielectric material from a pot through a sprue into the mold cavity with a plunger.

18. An integrated circuit device, comprising:
a first electronic component;
a second electronic component; and
a preformed spacer comprising polymer matrix material separating the first electronic component and the second electronic component.

19. The integrated circuit device of claim 18, wherein at least one of the first electronic component and the second electronic component comprises a semiconductor die.

20. The integrated circuit device of claim 19, wherein the second electronic component comprises a carrier substrate.

21. The integrated circuit device of claim 20, wherein the carrier substrate comprises one of an interposer substrate and a circuit board.

22. A method of forming an integrated circuit device, comprising:
forming a spacer having a selected length, width and height from a dielectric material;
placing the spacer on a first surface of a first component; and
placing a second component on the spacer.

23. The method of claim 22, further comprising configuring the first component as a semiconductor die.

24. The method of claim 23, further comprising configuring the second component as a semiconductor die.

25. The method of claim 23, further comprising configuring the second component as a carrier substrate.

26. The method of claim 22, wherein placing the spacer and placing the second component are performed by a single tool.

27. The method of claim 22, further comprising:
placing a flowable dielectric material into a mold cavity; and
solidifying the flowable dielectric material within the mold cavity to form the spacer.

28. The method of claim 22, further comprising:
placing a flowable dielectric material into a mold cavity;
solidifying the flowable dielectric material within the mold cavity to form a spacer wafer; and
slicing the spacer wafer to form at least one spacer.

29. The method of claim 22, further comprising:
placing a flowable dielectric material into a mold cavity having a first plurality of parallel runners and a second plurality of parallel runners positioned therein, the first plurality of parallel runners and the second plurality of parallel runners being orthogonal to one another and defining sub-cavities each configured to form an individual spacer; and
solidifying the flowable dielectric material within the mold cavity to form individual spacers in the sub-cavities between the first plurality of parallel runners and the second plurality of parallel runners.

30. A method of forming spacers for use in a semiconductor device assembly, the method comprising:
longitudinally feeding a sheet of dielectric material from a roll;
cutting a strip of the dielectric material transverse to a direction of feed and of a width corresponding to one lateral dimension of spacers to be formed; and
cutting the strip into segments having a length corresponding to another lateral dimension of spacers to be formed.

31. An electronic system, comprising:
a processor; and
memory in the form of a semiconductor device assembly, the semiconductor device assembly comprising at least two electronic components separated by a preformed spacer comprising a dielectric material.
